(19) United States
(12) Patent Application Publication
(10) Pub. No.: US 2014/0067297 A1
(43) Pub. Date: Mar. 6, 2014

(54) Optimized method for thermal management of an electrochemical storage system

(71) Applicants: Eric Prada, Lyon (FR); Valérie Sauvant-Moynot, Lyon (FR)

(72) Inventors: Eric Prada, Lyon (FR); Valérie Sauvant-Moynot, Lyon (FR)

(73) Assignee: IFP ENERGIES NOUVELLES, Rueil Malmaison Cedex (FR)

(21) Appl. No.: 14/114,235

(22) PCT Filed: Apr. 26, 2012
(86) PCT No.: PCT/FR2012/000162

§ 371 Date: Oct. 28, 2013

(30) Foreign Application Priority Data
May 4, 2011 (FR) 11/01376

(51) Int. Cl. G01R 31/36

(52) U.S. Cl. CPC G01R 31/3651
USPC 702/63

(57) ABSTRACT

The present invention relates to an optimized method for thermal management of the surface and core temperature of an electrochemical system under nominal and extreme operating conditions. For applications relating to hybrid and electric vehicles, the thermal state (T) at the surface and in the core of the constituent elements of the system has to be controlled in order to prevent thermal runaway, fire and explosion risks. Reconstruction of the internal characteristics that are not directly measurable, such as the temperature in the core of the elements, is carried out using an electrical, thermal and thermochemical runaway model of the battery.

### CROSS REFERENCE TO RELATED APPLICATION

Reference is made to French application Ser. No. 11/01.376, filed May 4, 2011, which application is incorporated herein by reference in its entirety.

### BACKGROUND OF THE INVENTION

1. Field of the Invention

The present invention relates to a method for estimating the core temperature of a constituent element of an electrochemical system for electrical energy storage, of the battery type, which is not directly measurable, and to a battery management system.

2. Description of the Prior Art

The electrochemical battery is notably one of the most critical components of a hybrid or electric vehicle. The battery voltage and temperature operating window defined by the manufacturer has to be complied with in order to guarantee the performances and the safety of the electrochemical system, in particular for Li-ion technologies. The voltage of an element is a characteristic considered to be homogeneous in the element in the art because it results from electronic movements in the conducting materials, such as the manifolds. On the other hand, the temperature of an element is not a homogeneous characteristic during the use of a battery because the thermal transport phenomena are not very fast.

The initial thermal state of the battery covers a wide temperature range, typically between −40° C. and +70° C. depending on the outside temperature. The thermal state during operation evolves as a function of the battery draw under charge and discharge conditions, the design and the environment of the battery. Common thermal state estimators are limited to measurements with thermocouples positioned at the surface of the cells or on the connections between the cells. The core temperature of the cells is however never effectively known. A more precise and reliable estimation of the skin and core thermal state would have many advantages, enabling the vehicle supervisor to prevent overheating in the core temperature in the center of the system. Indeed, during operation, high thermal gradients develop between the surface and the core of the constituent cells of an electrochemical pack for electrical energy storage. Critical current operation conditions and unsuitable thermal conditioning can cause very high thermal gradients within the system and lead to risks of thermal runaway, fire or even explosion. Apart from the safety aspects, control of the internal thermal gradient would advantageously allow aging of the elements to be reduced and increase the life thereof.

Proper operation of the vehicle is based on a smart battery management system (commonly referred to as BMS) that operates the battery in complete safety, with the best compromise between the various electrical and thermal dynamic load levels.

The BMS has multiple functionalities of carrying out current, voltage and skin temperature measurements at the level of the cells and/or the modules, estimating the state of charge (SoC), the state of health (SoH) and calculating, from these measurements and estimations, the energy and the power available in real time. It also defines the current thresholds entering and leaving the battery, it controls cooling, and finally it fulfils certain safety missions (for example by activating/deactivating some modules). Precise and reliable knowledge of the state of charge (SoC), the state of health (SoH) and the thermal state (T) is essential for the BMS.

The state of charge (SoC) of a battery is the available capacity thereof (expressed as a percentage of its nominal capacity). Knowing the SoC allows estimation of how long the battery can continue to supply energy at a given current or how long it can absorb energy. This information conditions the operation of the vehicle and notably the management of the energy among its components.

During the life of a battery, its performances tend to degrade gradually due to the physical and chemical variations that occur during use, until the battery becomes unusable. The state of health (SoH), which is the available capacity after recharging (expressed in Ah), thus is a measurement of the point that has indeed been reached in the life cycle of the battery.

The thermal state (T) is conventionally given by measuring the skin temperature.

Safe operation of the battery under nominal and extreme conditions is provided by the battery management system or BMS. Among its functions is controlling cooling of the battery and fulfilling certain safety missions by activating/deactivating for example some modules according to the current, voltage and skin temperature measurements collected at the level of the cells and/or modules. To date, there are no commercial elements equipped with a temperature detector (thermocouple for example) for direct measurement of the core temperature. Thus, detection of the thermal runaway initiation is not anticipated synchronously with the operation of the battery since the heat produced by the exothermic thermochemical reaction within the element has to diffuse up to the wall and to produce significant heating to be detected by the BMS.

Estimation of the thermal state in the core of the battery is conventionally performed using off-line thermal models, but the thermal balance is very incomplete. For example, EP-1,816,700 A1 only considers the ohmic losses due to Joule effect.

Now, electrochemical systems for electrical energy storage have a thermal behavior that directly depends on the physical, chemical and electrochemical properties of the electrode materials that store the electrical energy in form of chemical energy. These electrochemical reactions can be endothermic or exothermic.

EP-880,710 (Philips) describes the use of a battery electrical and thermal mathematical model. This model however does not account for the behavior of the battery under extreme conditions when thermal runaway phenomena are involved.

The prior art in question thus does not describe methods comprising notably an optimized thermal balance and a description of the thermochemical runaway kinetics in order to estimate at any time the core temperature of the system from the known internal chemical concentrations, then to control and manage the thermal transfers within the cooling loops of the system, and to anticipate safety risks.

### SUMMARY OF THE INVENTION

The method of the invention provides management of an electrochemical battery, notably when used in a hybrid or electric vehicle, or in any other storage application relating to the production of intermittent energies such as wind or solar power, whether under nominal or extreme operating conditions. The nominal operating conditions of a storage system are defined by the manufacturer who specifies the voltage, current and temperature ranges allowing safe use of the battery. Extreme conditions correspond to an operation outside the nominal conditions, which are at voltage and/or temperature and/or current levels involving thermal runaway problems.

The method according to the invention allows the internal thermal, electrical and thermochemical runaway behavior of a battery to be simulated. Reconstruction of the internal thermal and chemical characteristics, from the skin to the core of the battery, allows real-time control of the fluidic cooling of the system under nominal and extreme operating conditions, by activating certain safeties to prevent or limit thermal runaway.

The method can also be useful off-line, notably for sizing a battery and optimizing the energy and heat management strategies according to the application concerned in order to limit aging of the elements induced by a high internal thermal gradient and to avoid extreme operating conditions that may lead to thermal runaway and explosions.

The invention relates to an improved method of estimating the thermal state of a rechargeable electrochemical system comprising electrodes, a separator and an electrolyte, wherein:
at least one input signal of at least one parameter representative of a physical quantity of the system is available,
an electrochemical and thermal model of the system is established, with concentrated parameters (0D), wherein the parameters are homogeneous within the electrodes and the separator, comprising at least a mathematical representation of a kinetics of electrochemical reactions that take place at the interfaces between each electrode and the electrolyte, and taking into account interface concentrations, a mathematical representation of a spatial accumulation of charges in double layer capacity at each electrode, a mathematical representation of a redistribution of charges at each electrode, a mathematical representation of a diffusion of ionic charges of the electrolyte through the electrodes and the separator,
From this model, the following is established:
   a material balance in all the phases of the system,
   a global electrical balance of the electric potential of the system,
   an energy balance of the system, comprising an optimized thermal balance accounting for the thermal diffusion phenomena between the surface and the core of the electrochemical system for calculating a core temperature,
the variations over time of all the internal electrochemical variables of the system are calculated and the core and skin thermal state of the system is estimated by generating at least one output signal through application of the model to the input signal.

Preferably, a thermochemical runaway balance is also established for the elements of the system, which accounts for the evolution of active species consumption as a function of the thermal decomposition reactions of the material of the constituent elements of the system.

Advantageously, the optimized thermal balance allows calculation of the core temperature of the system by means of a pseudo-1D approach within the constituent elements of the system taking account of the net heat flux through the electrochemical system at ambient temperature and the thermal resistance characteristic of the system.

Preferably, the core temperature Tᵢₙₜ of the system is given by:

$${T}_{int} ( t ) = {T}_{surf} ( t ) ( 1 + {R}_{th , int} \frac{{ϕ}_{tra / gen} ( t )}{{T}_{surf} ( t ) - {T}_{a} ( t )} ) - {T}_{a} ( t ) ( \frac{{R}_{th , int} {ϕ}_{tra / gen} ( t )}{{T}_{surf} ( t ) - {T}_{a} ( t )} ) \qquad ( 8 )$$

where Tₛᵤᵣ is the surface temperature of the system;
R_{th,int} is the thermal resistance characteristic of the system;
φ_{tra/gen} is the net heat flux through the battery calculated as the difference between the internal and external fluxes, that is φ=φ_{gen}−φₜᵣₐ, the internal heat flux generated by the activity of the electrochemical cell and the flux transferred to the ambient air at a temperature Tₐ.

Advantageously, the electrochemical model accounts for the aging of the electrochemical system by determining a decrease in the maximum concentration of charge carriers in the electrolyte and an increase in the internal resistance of the electrochemical system.

Preferably, the thermodynamic equilibrium potential of each electrode is described by a thermodynamic (Nernst, Margules, Van Laar, Redlich-Kister) or analytical (polynomial, exponential for example) mathematical relation.

The potential and/or the state of charge and/or the state of health and/or the surface and core temperatures of the electrochemical system are preferably recorded as an output signal.

The invention also relates to a smart system for management of a rechargeable electrochemical storage system comprising electrodes, a separator and an electrolyte, including:
an input connected to a measuring device on the electrochemical system, for receiving an input value of at least one parameter representative of a physical quantity of the electrochemical system;
a processor for generating at least one output signal of at least one characteristic calculated by the method according to the invention;
an information/control system for providing information on the physical quantity of the electrochemical system and/or for controlling charge/discharge and/or cooling of the electrochemical system in response to the output signal of the processor and/or a comparison device.

Preferably, in the management system according to the invention, the processor comprises a recursive filter.

The invention also relates to the use of the management system for on-board control and real-time energy management of a rechargeable electrochemical storage system in operation.

The invention also relates to the use of the management system for control and management of a charger/discharger.

The method according to the invention can be used for off-line sizing of an electrochemical battery.

The invention finally relates to a simulator of the electrical and thermal behavior of a rechargeable electrochemical storage system under nominal and extreme conditions, comprising:
an input for receiving an input value of at least one parameter representative of a physical quantity of the electrochemical system; and
a processor for generating at least one output characteristic calculated by the method according to the invention.

The mathematical and physical model used in the method according to the invention, referred to as concentrated-parameter model, is based on the assumption that the concentrations of the species and the other variables are homogeneous in each region of the electrochemical system corresponding typically to the electrodes, the separator and the compartment for collecting the gaseous species. It is the zero-dimensional (0D) homogeneous approximation.

Besides, a pseudo-1D approach or method is used within the constituent cells of the system to account for the thermal diffusion aspects between the surface and the core of the system.

Coupled with the pseudo-1D approach or method, the 0D model of the method according to the invention (referred to as concentrated-parameter model) can calculate the variations over time of all the internal electrochemical variables of at least one electrode of the battery, and in particular of the core thermal state under nominal and extreme operating conditions. Since one of the inputs of the model is the current at the battery terminals, the simulated cases depend on the selection of the latter variable.

The quantities that can be used as input signals of the model are, in the case of an electrochemical battery: intensity I, ambient temperature T, potential V, or the electrical power required from the storage system.

Advantageously, the thermodynamic equilibrium potential of the system is described by a thermodynamic mathematical (Nernst, Margules, Van Laar, Redlich-Kister) or analytical relation (polynomial, exponential, . . . ).

Advantageously, the thermochemical runaway reactions are coupled with the system of equations relative to the operation under nominal conditions.

Advantageously, electrode aging reactions are coupled with the system of equations relative to the operation under nominal and extreme conditions.

The potential and/or the state of charge and/or the state of health and/or the temperature of the electrochemical system can be recorded as an output signal.

Advantageously, for an application of the method to a battery simulator, output signals are recorded which are the voltage at the terminals of the electrochemical system and the surface and core temperature of the electrochemical system.

Advantageously, for an application of the method to a battery state estimator, output signals are recorded which are the state of charge, the state of health and the surface and core temperature of the electrochemical system.

The invention also relates to a system for smart management of an electrochemical storage system of battery type (notably referred to as Battery Management System BMS), comprising:

an input connected to a measuring device on the battery, which receives an input value of at least one parameter representative of a physical quantity of the battery;
a processor for generating at least one output signal of at least one characteristic calculated by the method using the 0D electrochemical model according to the invention;
an information/control system providing information on the physical quantity of the battery and/or controlling charge/discharge and/or cooling of the battery in response to the output signal of a processor and/or comparator.

The processor can comprise a recursive filter (of Kalman type for example).

The management system can be used for on-board control and real-time energy management of a storage system in operation, notably in a hybrid or electric vehicle.

The invention comprising the management system also relates to a battery charger/discharger.

The invention further relates to a simulator of the electrical and thermal behaviour of the battery under nominal and extreme conditions, comprising:

an input for receiving an input value of at least one parameter representative of a physical quantity of a battery; and
a processor for generating at least one output characteristic calculated by the method according to the invention.

The battery simulator notably allows simulation of the surface and core thermal and electrical behavior of the battery.

The invention also relates to an electrochemical impedance spectroscopy simulator using the method according to the invention.

The method according to the invention allows implementation of a battery sizing and/or design process.

The invention also relates to a simulator of the hybrid or electrical vehicle system comprising a traction battery, using the method according to the invention for estimating the internal characteristics of the battery.

### BRIEF DESCRIPTION OF THE DRAWINGS

FIG. 1 diagrammatically shows a Li-ion battery cell where Neg designates the carbon compound-based porous negative electrode, LiM0₂ the metal oxide-based porous positive electrode, Sep the separator insulating electrically the two electrodes, Col the current collectors and x the prevalent direction.

FIG. 2 diagrammatically shows the Kalman filter that is applied to an electrochemical cell according to the method of the invention, with X being the internal state calculated by the estimator, with U being the input, Y being the output, and F being variation of the internal state according to the model.

FIGS. 3a, b, c and d show an example of voltage (V) (a and b) and skin temperature (° C.) (c and d) prediction of the model according to the invention for a Li-ion 2.3 Ah battery manufactured by A123s, used at different discharge regimes.

FIG. 4 shows the skin (thin dotted line) and core (thick dotted line) temperature predictions of the model according to the invention for the Li-ion 2.3 Ah battery manufactured by A123s, compared with the experimental data (full line), used according to a dynamic current regime corresponding to a HPPC profile, underlining the temperature differences between core and skin.

FIG. 5 shows the thermal runaway results during a test where the cell is placed in an oven at 155° C. (cell temperature in ° C. as a function of the time in s). The core temperature is simulated by the model for extreme operating conditions.

FIG. 6 shows the laws of consumption evolution in percent as a function of time (in s) of the active species, such as the interphase layer referred to as SEI between the active matter and the electrolyte (C_{SEI}), the negative electrode (C_{NE}), the positive electrode (C_{PE}) and the electrolyte (C_{E}) during the test at 155° C.

FIGS. 7a, b and c show the evolutions over time (in s) of the voltage (V) of a cell and of the skin (full line) and core (dotted line) temperatures during cell operation under charge and discharge conditions (pulses) without thermal management.

FIGS. 8a and 8b respectively show the air and water flow rate control laws in m³/h for obtaining the core temperature setpoint value of 45° C. in the thermal management system according to the invention.

### DETAILED DESCRIPTION OF THE INVENTION

The current at the cell terminals is considered as an input of the model, whereas the voltage is one of its outputs. The input signals, current and temperature, are representative of physical quantities measured on the battery. A processor based on Butler-Volmer's equations, the charge balance, the material balance, the aging kinetics, the thermochemical runaway balance, the energy balance and a pseudo-1D thermal approach calculate the state of the battery on the basis of the input signals and generate output signals derived from the calculation, such as the potential, the state of charge, the state of health and the skin and core temperatures.

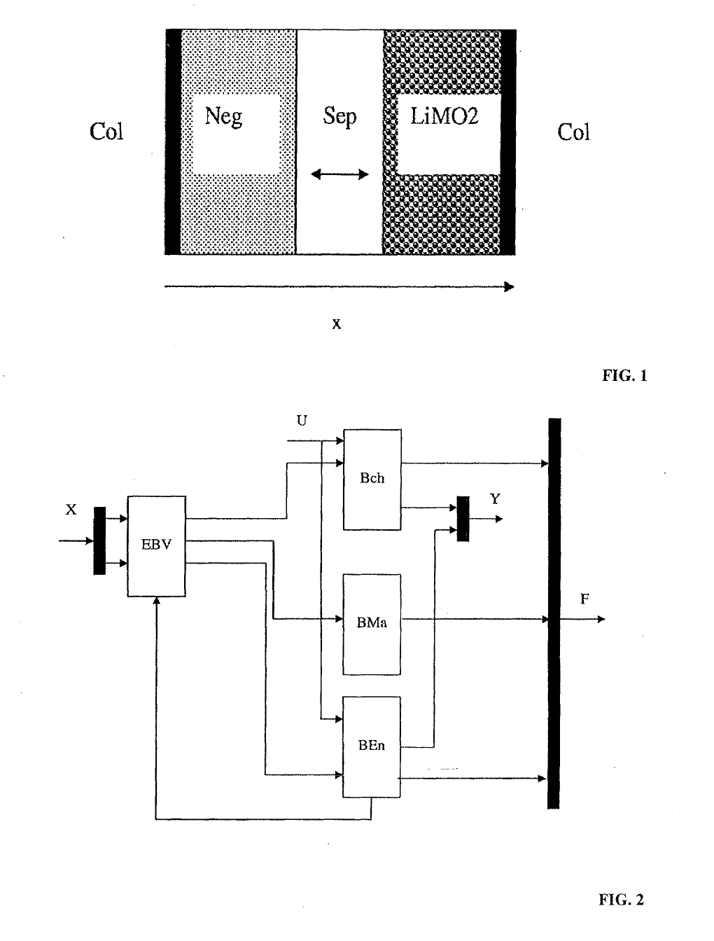

FIG. 1 diagrammatically shows a Li-ion battery cell where Neg designates the carbon compound-based porous negative electrode, LiM0₂ the metal oxide-based porous positive electrode, Sep the separator insulating electrically the two electrodes, Col the current collectors and x the prevalent direction. In order to guarantee ionic conduction between the two electrodes when there is a current flow, the electrodes and the separator are impregnated with a lithium salt-concentrated organic electrolyte, liquid or gel.

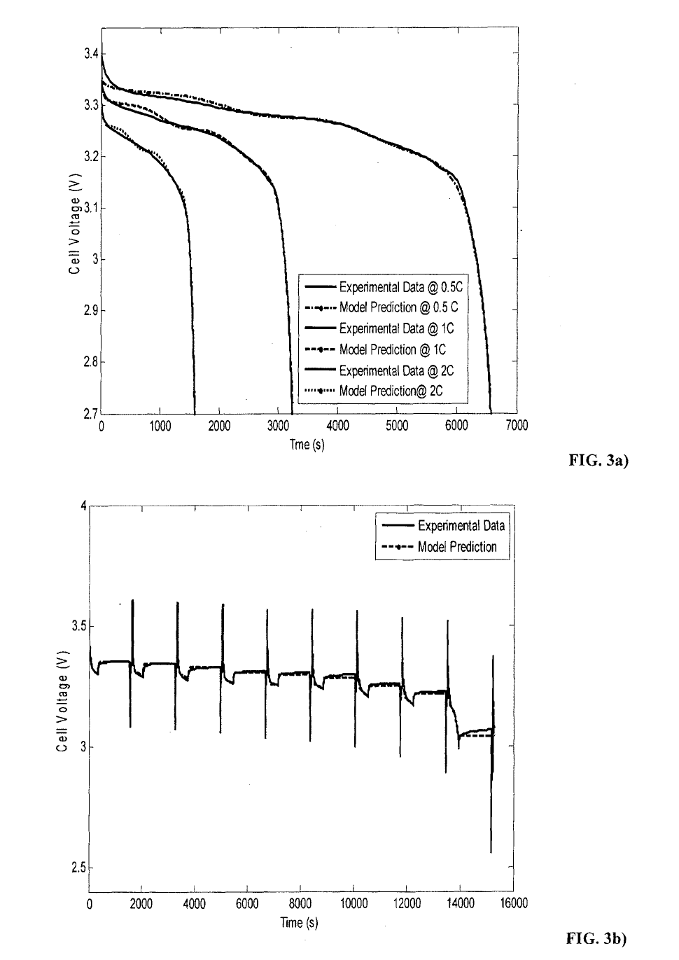

FIG. 2 diagrammatically shows the Kalman filter that is applied to an electrochemical cell according to the method of the invention, with X being the internal state calculated by the estimator, with U being the input, Y being the output, and F being variation of the internal state according to the model.

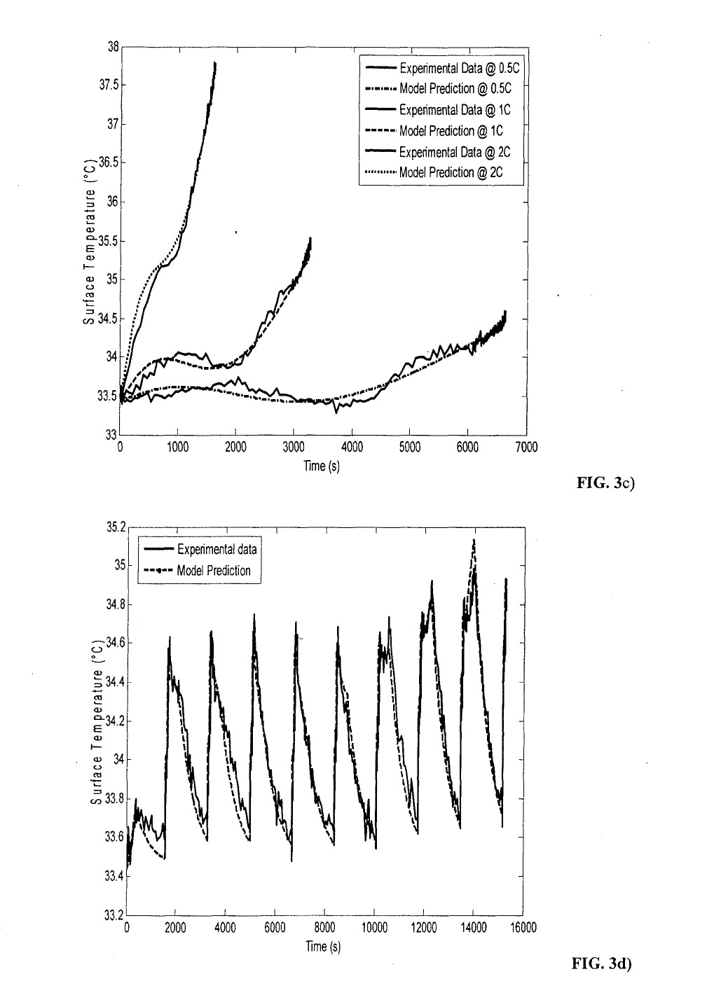

FIGS. 3a, b, c and d show an example of voltage (V) (a and b) and skin temperature (° C.) (c and d) prediction of the model according to the invention for a Li-ion 2.3 Ah battery manufactured by A123s, used at different discharge regimes: 0.5, 1 and 2C (a and c), and also according to a dynamic current regime corresponding to a HPPC profile (b and d). The results simulated by a physical 0D model according to the invention (dotted line) are compared with the experimental results (full line) and they indeed account for the reversible (endothermic and/or exothermic) and irreversible (exothermic only) heat flux contribution phenomena.

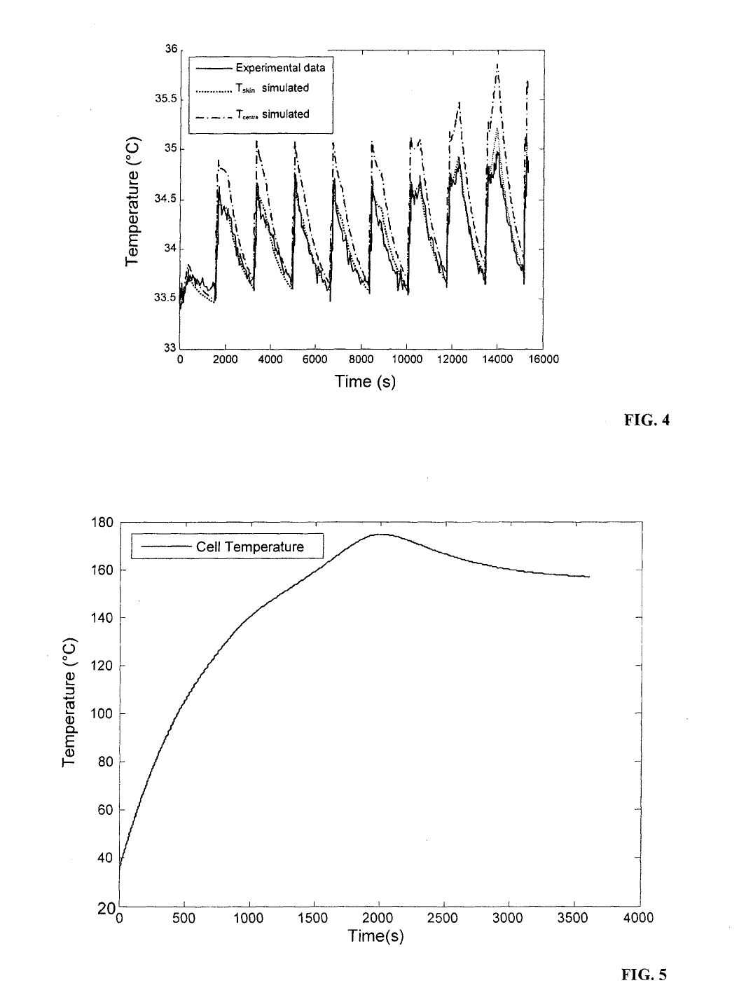

FIG. 4 shows the skin (thin dotted line) and core (thick dotted line) temperature predictions of the model according to the invention for the Li-ion 2.3 Ah battery manufactured by A123s, compared with the experimental data (full line), used according to a dynamic current regime corresponding to a HPPC profile, underlining the temperature differences between core and skin.

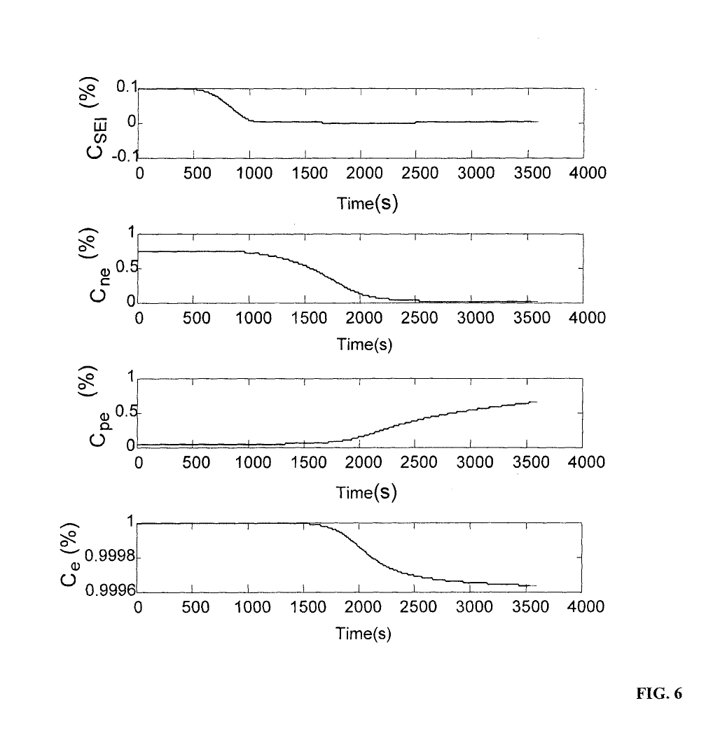

FIG. 5 shows the thermal runaway results during a test where the cell is placed in an oven at 155° C. (cell temperature in ° C. as a function of the time in s). The core temperature is simulated by the model for extreme operating conditions.

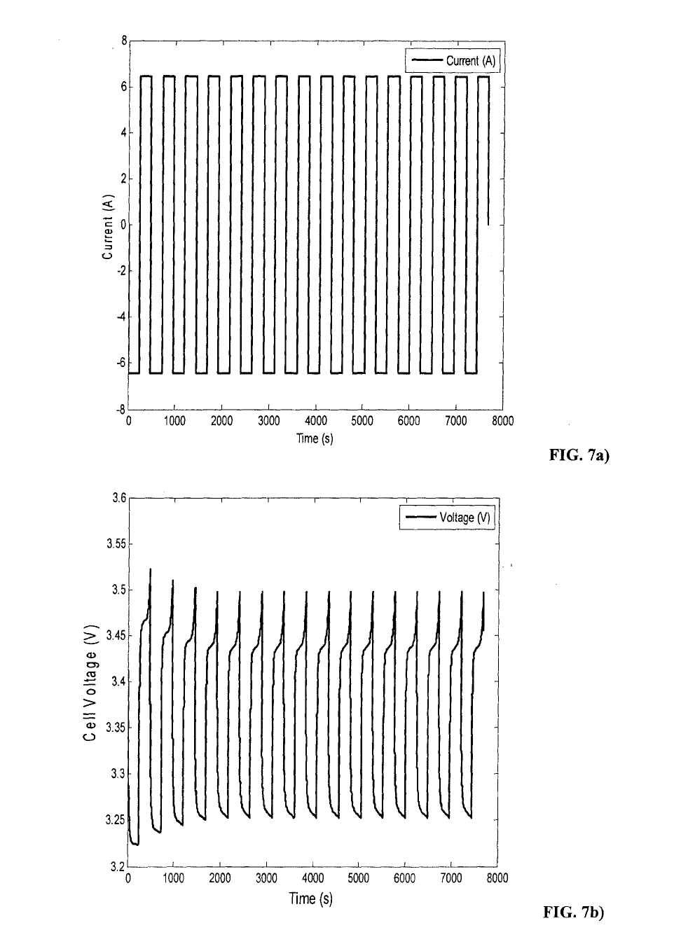

FIG. 6 shows the laws of consumption evolution in percent as a function of time (in s) of the active species, such as the interphase layer referred to as SEI between the active matter and the electrolyte (C_{SEI}), the negative electrode (C_{NE}), the positive electrode (C_{PE}) and the electrolyte (C_{E}) during the test at 155° C.

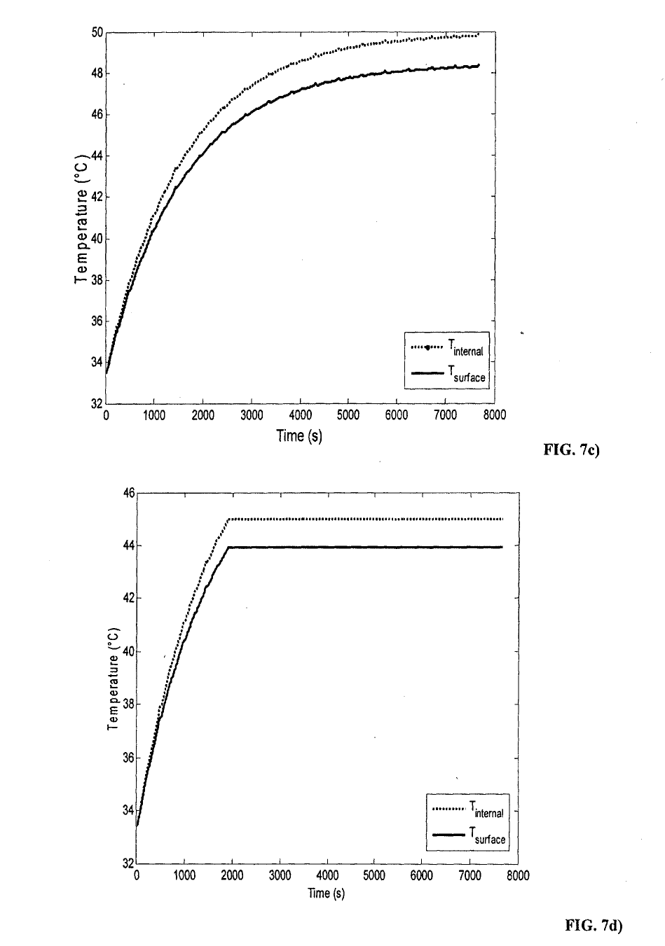

FIGS. 7a, b and c show the evolutions over time (in s) of the voltage (V) of a cell and of the skin (full line) and core (dotted line) temperatures during cell operation under charge and discharge conditions (pulses) without thermal management. The core temperature increases more than the surface temperature, in an uncontrolled manner. In order to control this aspect, cooling thermal management laws based on the invention are applied to maintain the skin or core temperature at a given temperature. In FIG. 7d, the setpoint value is 45° C. in the core during intensive current cycles. FIG. 7d shows the evolution of the skin and core temperatures under control, by comparison with FIG. 7c showing the evolution of the temperatures without control.

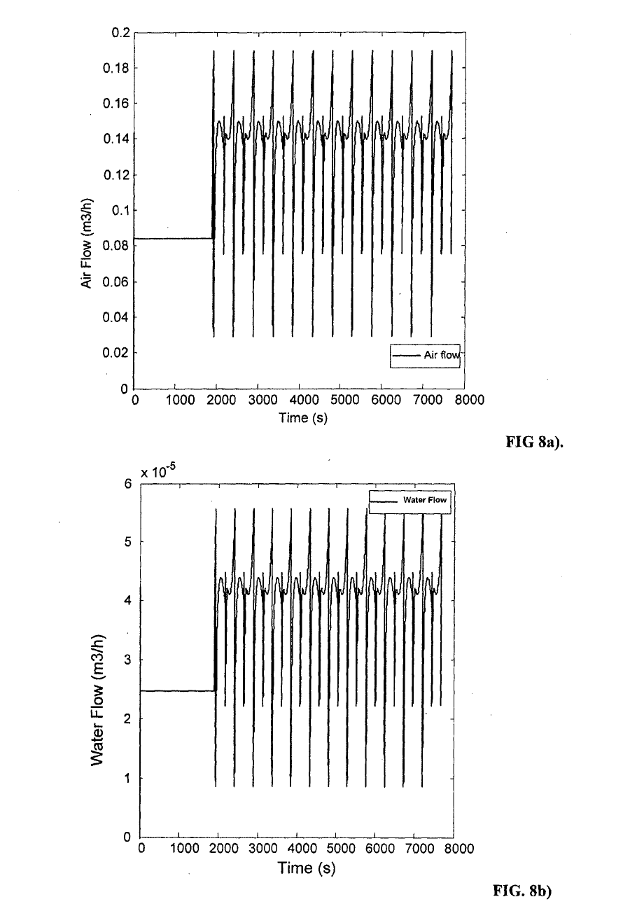

FIGS. 8a and 8b respectively show the air and water flow rate control laws in m³/h for obtaining the core temperature setpoint value of 45° C. in the thermal management system according to the invention.

Thermal Electric and 0D Thermochemical Runaway Mathematical Model of the Storage System

As described above, the 0D mathematical model referred to as concentrated-parameter model is based on the assumption that the concentrations of the species and the other variables are homogeneous in each region of the electrochemical system (of the battery cell for example) corresponding typically to the electrodes, the separator and the compartment intended to collect the gaseous species. This is referred to as zero-dimensional (0D) homogeneous approximation.

Electrical Balance:

The generic 0D mathematical model establishes a global electrical balance of the electrical potential on the cell:

$$V ( t , T ) = {V}^{∘} ( t , T ) + {η}_{Ω} ( t , T ) + {\sum }_{i = 1}^{N} {η}_{cti} ( t , T ) + {\sum }_{i = 1}^{{N}^{′}} {η}_{ci} ( t , T ) \qquad ( 1 )$$

where V(t,T) is the voltage at the cell terminals, V° (t,T) is the thermodynamic voltage of the cell, η_{cti} are charge transfer overvoltage terms of the energy storage that depend on the current I applied, η_{ci} are concentration overvoltage terms linked with the diffusive phenomena that depend on the current I applied and η_{Ω} is an ohmic overvoltage involving the internal resistance of the system, resulting from the conductivities of the solid and liquid phases.

The equations allowing the zero-dimensional model used in the method according to the invention to be implemented are explained hereafter.

Thermochemical Runaway Balance of the System Constituents:

Electrochemical systems contain materials that decompose under the effect of high temperatures. Each constituent of the system, upon thermochemical decomposition thereof, releases a decomposition source heat flux S expressed as follows:

Sᵢ(t)=Hᵢ(t)Wᵢ(t)Rᵢ(t) (2)

where H is the reaction enthalpy of the material, W the density of the material and R the thermal decomposition reaction rate. The thermal decomposition rate is expressed as follows:

$${R}_{i} ( t ) = {A}_{i} \times exp ( \frac{- {E}_{a , i}}{{RT}_{surf / int}} ) \times {[ X ]}_{i} ( t ) \qquad ( 3 )$$

where A is the decomposition factor, Ea the thermal activation energy of the decomposition reaction and X the concentration of active material considered.

During the thermochemical decomposition reaction, the law of evolution of the active species consumption is expressed as follows:

$$\frac{d {[ X ]}_{i}}{d t} = \pm {R}_{i} \qquad ( 4 )$$

Thermal Balance:

The temperature of the cell can be calculated as an output of the energy balance. On the one hand, the internal heat flux φ_{gen} generated by the electrochemical cell activity under nominal operating conditions, which advantageously takes account of thermal runaway reactions, is given by:

$${ϕ}_{gen} ( t ) = {\sum }_{z}^{ } {J}_{z} ( t ) ( {U}_{eq , z} - T ( t ) \frac{d {U}_{eq , z}}{d T} ) A ( z ) - V ( t ) I ( t ) + {S}_{tot} ( t ) \qquad ( 5 )$$

where term (U_{eq,ref,z}-V) can be associated with the irreversible losses for each electrochemical reaction z, knowing that A(z) represents here the electroactive surface and Jz the current density, whereas the reversible generation term T dU_{eq,ref,z}/dT is directly related to the entropy variations due to the electrochemical reactions. Term Sₜₒₜ accounts for the exothermic decomposition reactions of all or part of the electrochemical system once the cell temperature exceeds the thermochemical decomposition trigger threshold temperature.

On the other hand, the flux transferred to the ambient at temperature Tₐ, φₜᵣₐ is given by Fourier's law:

φₜᵣₐ(t)=hA_{cell}(T(t)−Tₐ) (6)

where h is a thermal transfer coefficient associated with the convection and radiation phenomena, and A_{cell} is the surface area of the cell. The net thermal flux through the battery, φ, can be readily calculated as the difference between the internal and external fluxes, i.e. φ=φ_{gen}−φₜᵣₐ. The amount of heat stored in the battery, obtained by integration of the heat flux over time, allows calculating the temperature of the battery according to the relationship:

$${M}_{cell} {C}_{p} \frac{d T ( t )}{d t} = {ϕ}_{gen} ( t ) - {ϕ}_{tra} ( t ) \qquad ( 7 )$$

where Cₚ is the specific thermal capacity of the cell and M_{cell} the mass thereof.

The core temperature of the system is calculated with the relation as follows with a pseudo-1D approach according to the invention:

$${T}_{int} ( t ) = {T}_{surf} ( t ) ( 1 + {R}_{th , int} \frac{{ϕ}_{tra / gen} ( t )}{{T}_{surf} ( t ) - {T}_{a} ( t )} ) - {T}_{a} ( t ) ( \frac{{R}_{th , int} {ϕ}_{tra / gen} ( t )}{{T}_{surf} ( t ) - {T}_{a} ( t )} ) \qquad ( 8 )$$

where R_{th,int} is the thermal resistance characteristic of the system being studied, that is the electrode stack.

The aging kinetics of the Li-ion batteries, considered as parasitic or secondary reactions, are commonly given by the Butler-Volmer relation explained on the negative electrode in the relation as follows:

$${J}_{para , neg} = - {J}_{0 para , neg} ( T ) exp ( - \frac{{α}_{red} F}{RT} ( {ΔΦ}_{neg} - {U}_{para , neg} ) ) \qquad ( 9 )$$

where Δφ_{neg} is the electrode overvoltage and U_{para,neg} is the equilibrium potential of the electrolyte reduction on the negative electrode.

The capacity loss of the battery is related to the decrease in the ionic charge carriers concentration in the electrolyte, correlated with the current density of the electrolytic reduction on the negative electrodes most often, corresponding to the formation of an interphase layer referred to as “SEI” between the active matter and the electrolyte. The concentration variation of the lithium present in the electrolyte is given by:

$$\frac{d {C}_{e}}{d t} = \frac{{J}_{para , neg}}{F {δ}_{SE I}} \qquad ( 10 )$$

where δ_{SEI} is the thickness of layer SEI. The rate of growth of layer SEI, under the assumption of a kinetic control limited by an ion-diffusion mechanism through the layer, is given by the relation as follows:

$$\frac{d {δ}_{SEI}}{d t} = \frac{2 πD}{{δ}_{SEI}} - \frac{{M}_{s}}{ρ F} {J}_{para , neg} \qquad ( 11 )$$

where ρ and Ms are respectively the density and the molecular mass of layer SEI, and D is the diffusion coefficient of the solvent within layer SEI.

Cooling Control and Optimized Management Law

Through fine knowledge of the thermal evolution of the electrochemical system under nominal or extreme operating conditions, it is possible to calculate and to advocate at any time the value of the cooling fluid flow rate as follows:

$$D ( t ) = \frac{{ϕ}_{tra} ( t )}{{C}_{th} ρ ( {T}_{surf / int} ( t ) - {T}_{a} ( t ) )} \qquad ( 12 )$$

where Cₜₕ is the heat-capacity rate of the heat-carrying fluid, ρ the density of the heat carrier, T_{surf/int} the target temperature desired either at the surface or in the core of the system, and Tₐ the temperature of the heat carrier. If the battery is to be operated under quasi-isothermal conditions (T is constant), the flow rate of the heat carrier has to be controlled according to the expression as follows:

$$D ( t ) = \frac{{ϕ}_{gen} ( t )}{{C}_{th} ρ ( {T}_{surf / int} ( t ) - {T}_{a} ( t ) )} \qquad ( 13 )$$

The other quantities appearing in the equations of the method are treated as parameters to be calibrated.

Material Balance and Definition of the State of Charge:

The state of charge of the cell in the method according to the invention, q(t), is given by the concentration of one of the reactive species X according to relation (14):

$$SOC ( t ) = γ + δ \frac{{[ X ]}_{t}}{{[ X ]}_{max}} \qquad ( 14 )$$

wherein γ and δ are functional quantities characteristic of the electrode materials.

This calculation is markedly distinguished from the calculation known in the prior art, referred to as “Coulomb counting”, which gives:

$$\frac{d q ( t )}{d t} = \frac{I ( t )}{{Q}_{max}} \qquad ( 15 )$$

The relation between Xₘₐₓ and Qₘₐₓ is given by:

Qₘₐₓ=κF[X]ₘₐₓ (16)

wherein F is Faraday's constant and K is a functional quantity characteristic of the geometry of the limiting electrode.

The estimation of q is thus based on the estimation of X, whereas this variable is not directly measurable from a battery, in particular on board a vehicle.

Examples of Application to a Li-Ion Technology

Case of a Li-Ion Battery

In the case of a Li-ion battery, the active species are metal oxides for the positive electrode and carbon compounds, metals or metal oxides for the negative electrode. A Li-ion cell is diagrammatically shown in FIG. 1.

The electrochemical reactions at the positive electrode are, during charging:

Li₁₋ₓMO₂+xe⁻+xLi⁺→LiMO₂ (17)

whereas, at the negative electrode, by taking the example of a carbon compound:

Li_{y}C₆→yLi⁺6C+ye⁻ (18)

The thermal behavior of the electrode materials can vary significantly with the state of charge (SoC) of the electrodes. Here, the entropic term dU_{eq}/dT shows endothermic and exothermic sections depending on the SoC. The variations of this parameter are modelled by a polynomial mathematical expression.

In a Li-ion system, the main thermochemical decomposition reactions considered according to a simplification of the invention are:

| Decomposition reaction of the system | Initiation temperature range |
|---|---|
| constituents | (° C.) |
| Decomposition of the passive layer at the | 90° C. < T < 120° C. |
| surface of the negative electrode | |
| Decomposition of the negative electrode | T > 120° C. |
| Decomposition of the positive electrode | T > 120° C. |
| Decomposition of the electrolyte | T > 200° C. |

Each decomposition reaction is modelled by Equations (1, 2, 3, 4). The parameters of the model are given in the table below:

| Parameters of a model according | Values of the |
|---|---|
| to the invention | Parameters |
| A_sei | 1.667e15 |
| A_ne | 2.5e13 |
| A_pe | 6.667e13 |
| A_e | 5.14e25 |
| Ea_sei | 1.3508e5 |
| Ea_ne | 13508e5 |
| Ea_pe | 1.396e5 |
| Ea_e | 2.74e5; |
| H_sei | 257 |
| H_ne | 1714 |
| H_pe | 314 |
| H_e | 155 |
| W_n | 6.104e5 |
| W_p | 1.221e6 |
| W_e | 4.069e5 |

Indices p, e, n and sei respectively represent the various components of the system, which are the positive electrode, the electrolyte, the negative electrode and the passivation layer developed at the surface of the negative electrode.

The overall voltage of the system is expressed as follows:

V=V°+η_{Ω}+η_{ct}+η_{c} (19)

where ηΩ represents the ohmic overvoltage, □ct represents the charge transfer overvoltage and η_{c} represents the concentration overvoltage.

The electrical and thermal behavior equations have been calibrated under different operating conditions. The electrical and thermal simulation results have been compared with the experimental data as illustrated in FIGS. 4a, b, c and d.

A thermal runaway test where a cell has been placed in an oven at 155° C. is shown in FIG. 5.

A thermally-managed flow rate control test for isothermal maintenance at a core temperature T=45° C. has been conducted with a fast battery charge/discharge protocol on an A123 Systems battery. The results are shown in FIGS. 7 and 8.

Presentation of the Recursive Filter

The method advantageously uses a recursive filter for estimating the state of the dynamic system from the available measurements, which is diagrammatically shown in FIG. 2. Notable characteristics of this estimation problem are the fact that the measurements are affected by noise and that the modelled system according to the invention is highly non-linear. A recursive filter preferably used in the method is the known extended Kalman filter.

According to the model of the method, the state vector of the electrochemical battery cell (FIG. 2) is written: x={SOC, η_{ct}, η_{c}, T}, where the first component is related to the state of charge to be estimated by Equation (11). The measurements available are the voltage at the cell terminals and the temperature of the battery, which represent output y of the model, and current Iₐₚₚ at the terminals, which represents input u of the model. According to the known recursive filter method, the equations of the model are reorganized into:

\ddot{x}=f(x,u)

y=h(x,u) (20)

Battery Electrical, Thermal Behavior and Thermochemical Runaway Simulator

The method according to the invention allows calculation of the variations over time of all the variables internal to the battery, and in particular of the thermal state. Since the input of the model is the current at the battery terminals, the simulated cases depend on the selection of the latter variable. For example, a controlled charge or discharge can be represented at constant current, or variable current depending on the profile fixed, or variable current depending on the voltage. The latter case is representative of the battery draw conditions in a vehicle, where the current imposed on the battery depends on the voltage, according to the characteristics of the associated electrical components (power electronics, electric motor(s), etc.). Typical electrical behavior prediction results obtained with a battery simulator using the models according to the invention are presented in FIG. 4 for the Li-ion battery. In both cases, the comparison of the results of the 0D model of the method according to the invention with the experimental results underlines the precision of the dynamic behaviour rendering obtained.

The presence of the energy balance in the 0D model and of the thermal runaway balance of the method according to the invention allows simulation of the thermal evolution of the system, coupled with the evolution of the electrical state given by Equation (1), under nominal and extreme conditions of use. Typical battery thermal behavior prediction results from a simulator using the models according to the invention are given in FIG. 4 for the case of the Li-ion battery.

Consequently, the method according to the invention can thus serve for sizing of the battery, definition, calibration and validation of the electrical and thermal management strategies, and finally optimization of the secured thermal management systems, as shown in FIGS. 7 and 8 with which the battery itself must necessarily be equipped. In fact, the thermal fluxes generated and the temperature of the battery are input variables for these systems, whose purpose is to adjust these fluxes and this temperature around allowable values.

The representation of the thermal transients thus allows synthesizing and validation of the control and optimization strategies associated with the thermal management systems. These strategies can thus benefit from the presence of a reduced model during their on-line use, so as to have estimations of certain variables that are not measurable (temperatures at specific points, thermal fluxes, etc.), or that are measurable, but with too long response times of the associated detectors.

Vehicle System Simulator

The 0D model according to the invention is also useful as a sizing tool for hybrid vehicle powertrains.

Typically, these applications require concentrated-parameter battery behaviour models capable of simulating the dynamic behavior of a traction battery more efficiently and reliably than static mapping models or mapping models of equivalent electric circuit type.

Sizing Method for Battery Production

Any battery production method based on a simulator of the electrical and thermal behavior of a battery will advantageously benefit from the 0D model of the method according to the invention, its minimized calculating time, its reliability and precision regarding prediction of the internal thermal characteristics of a battery under nominal and extreme operating conditions. This model can be coupled with a finite-element model. Thus, a battery manufacturing method can be implemented by sizing the battery with the method according to the invention.

1-13. (canceled)

14. A method of estimating the thermal state of a rechargeable electrochemical system comprising electrodes, a separator and an electrolyte, including at least one available input signal of at least one parameter representative of a physical quantity of the system, an electrochemical and thermal model of the system including parameters wherein the parameters are homogeneous within the electrodes and the separator, comprising at least a mathematical representation of a kinetics of electrochemical reactions that take place at interfaces between each electrode and electrolyte, and accounting for interface concentrations, a mathematical representation of a spatial accumulation of charges in a double layer capacity at each electrode, a mathematical representation of a redistribution of charges at each electrode, a mathematical representation of a diffusion of ionic charges of the electrolyte through the electrodes and the separator, comprising:
establishing a material balance in all the phases of the system, establishing a global electrical balance of the electric potential of the system, establishing an energy balance of the system, comprising an optimized thermal balance accounting for the thermal diffusion phenomena between a surface and a core of the electrochemical system for calculating a core temperature, calculating variations over time of all the internal electrochemical variables of the system are calculated and estimating a core and a skin thermal state of the system by generating at least one output signal by application of the model to the input signal.

15. A method as claimed in claim 14, comprising establishing a thermochemical runaway balance for elements of the system accounting for evolution of consumption of the active species consumption, a function of thermal decomposition reactions of constituent elements of the system.

16. A method as claimed in claim 14, comprising calculating an optimized thermal balance of the core temperature with pseudo-1D approach within constituent elements of the system accounting for a net heat flux of the electrochemical system at ambient temperature and thermal resistance characteristic of the system.

17. A method as claimed in claim 15, comprising calculating an optimized thermal balance of the core temperature with pseudo-1D approach within constituent elements of the system accounting for a net heat flux of the electrochemical system at ambient temperature and thermal resistance characteristic of the system.

18. A method as claimed in claim 10, wherein the core temperature Tᵢₙₜ of the system is given by:
$${T}_{int} ( t ) = {T}_{surf} ( t ) ( 1 + {R}_{th , int} \frac{{ϕ}_{tra / gen} ( t )}{{T}_{surf} ( t ) - {T}_{a} ( t )} ) - {T}_{a} ( t ) ( \frac{{R}_{th , int} {ϕ}_{tra / gen} ( t )}{{T}_{surf} ( t ) - {T}_{a} ( t )} ) \qquad ( 8 )$$
where T_{surf} is a surface temperature of the system;
R_{th,int} is a thermal resistance characteristic of the system;
φ_{tra/gen} is a net heat flux of the battery calculated as the difference between internal and external fluxes, φ=φ_{gen}−φₜᵣₐ with the internal heat flux being generated by activity of the electrochemical cell and flux transferred to the ambient air at a temperature Tₐ.

19. A method as claimed in claim 17, wherein the core temperature Tᵢₙₜ of the system is given by:
$${T}_{int} ( t ) = {T}_{surf} ( t ) ( 1 + {R}_{th , int} \frac{{ϕ}_{tra / gen} ( t )}{{T}_{surf} ( t ) - {T}_{a} ( t )} ) - {T}_{a} ( t ) ( \frac{{R}_{th , int} {ϕ}_{tra / gen} ( t )}{{T}_{surf} ( t ) - {T}_{a} ( t )} ) \qquad ( 8 )$$
where T_{surf} is a surface temperature of the system;
R_{th,int} is a thermal resistance characteristic of the system;
φ_{tra/gen} is a net heat flux of the battery calculated as the difference between internal and external fluxes, φ=φ_{gen}−φₜᵣₐ with the internal heat flux being generated by activity of the electrochemical cell and flux transferred to the ambient air at a temperature Tₐ.

20. A method as claimed in claim 14, wherein the electrochemical model accounts for aging of the electrochemical system by determining a decrease in a maximum concentration of charge carriers in the electrolyte and an increase in an internal resistance of the electrochemical system.

21. A method as claimed in claim 16, wherein the electrochemical model accounts for aging of the electrochemical system by determining a decrease in a maximum concentration of charge carriers in the electrolyte and an increase in an internal resistance of the electrochemical system.

22. A method as claimed in claim 17, wherein the electrochemical model accounts for aging of the electrochemical system by determining a decrease in a maximum concentration of charge carriers in the electrolyte and an increase in an internal resistance of the electrochemical system.

23. A method as claimed in claim 18, wherein the electrochemical model accounts for aging of the electrochemical system by determining a decrease in a maximum concentration of charge carriers in the electrolyte and an increase in an internal resistance of the electrochemical system.

24. A method as claimed in claim 19, wherein the electrochemical model accounts for aging of the electrochemical system by determining a decrease in a maximum concentration of charge carriers in the electrolyte and an increase in an internal resistance of the electrochemical system.

25. A method as claimed in claim 14, wherein a thermodynamic equilibrium potential of each electrode is described by a thermodynamic relation or an analytical mathematical relation.

26. A method as claimed in claim 15, wherein a thermodynamic equilibrium potential of each electrode is described by a thermodynamic relation or an analytical mathematical relation.

27. A method as claimed in claim 16, wherein a thermodynamic equilibrium potential of each electrode is described by a thermodynamic relation or an analytical mathematical relation.

28. A method as claimed in claim 18, wherein a thermodynamic equilibrium potential of each electrode is described by a thermodynamic relation or an analytical mathematical relation.

29. A method as claimed in claim 20, wherein a thermodynamic equilibrium potential of each electrode is described by a thermodynamic relation or an analytical mathematical relation.

30. A method as claimed in claim 14, wherein at least one of a potential, a state of charge, a state of health and surface, and core temperatures of the electrochemical system are recorded as an output signal.

31. A smart system for management of a rechargeable electrochemical storage system comprising electrodes, a separator and an electrolyte, comprising:
an input connected to a measuring device on the rechargeable electrochemical storage system, for receiving an input value of at least one parameter representative of a physical quantity of the electrochemical system;
a processor for generating at least one output signal of at least one characteristic calculated by steps of claim 14; and
an information control for providing information on a physical quantity of the electrochemical system and at least one of controlling charge, discharge and cooling of the electrochemical system in response to an output signal of at least one of a processor and/or a comparator.

32. A management system as claimed in claim 31, wherein the processor comprises a recursive filter.

33. A system as claimed in claim 31, comprising:
an on-board control and real-time energy management system of the rechargeable electrochemical storage system.

34. A system as claimed in claim 31, comprising:
a control and management system of a charger or discharger.

35. A system as claimed in claim 31, comprising:
an electrochemical battery.

36. A method in accordance with claim 14, comprising a simulator of electrical and thermal behavior of a rechargeable electrochemical storage system comprising:
an input for receiving an input value of at least one parameter representative of a physical quantity of the rechargeable electrochemical storage system; and
a processor for generating at least one output characteristic.
